(19) United States
(12) Patent Application Publication
(10) Pub. No.: US 2008/0268612 A1
(43) Pub. Date: Oct. 30, 2008

(54) METHOD OF FORMING ISOLATION LAYER IN SEMICONDUCTOR DEVICE

(76) Inventors: Whee Won Cho, Cheongju-si (KR); Cheol Mo Jeong, Icheon-si (KR); Jung Geun Kim, Seoul (KR); Suk Joong Kim, Icheon-si (KR); Jong Hye Cho, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/962,611

(22) Filed: Dec. 21, 2007

(30) Foreign Application Priority Data
Apr. 25, 2007 (KR) 2007-0040359

(51) Int. Cl. H01L 21/762

(52) U.S. Cl. 438/437; 257/E21.546

(57) ABSTRACT

The present invention discloses to a method of forming an isolation layer in a semiconductor device. In particular, the method of forming an isolation layer in a semiconductor device of the present invention comprises the steps of providing a semiconductor substrate on which a trench is formed; forming spacers on side walls of the trench; forming a first insulating layer to fill a portion of the trench such that a deposition rate on the semiconductor substrate which is a bottom surface of the trench and exposed between the spacers is higher than that on a surface of the space; and forming a second insulating layer on the first insulating layer so as to fill the trench with the second insulating layer. An O₃-TEOS layer on the exposed semiconductor substrate which is a bottom surface of the trench is grown faster than that on a surface of the spacer formed of an oxide layer or a nitride layer to prevent the O₃-TEOS layers grown on the side walls from coming into contact with each other, and so it is possible to inhibit a generation of a seam and to enhance a gap-filling characteristic for the trench.

### CROSS-REFERENCE TO RELATED APPLICATIONS

The priority benefit of Korean Patent Application No. 2007-0040359, filed on Apr. 25, 2007, is hereby claimed and the disclosure thereof is incorporated herein by reference in its entirety.

### BACKGROUND OF THE INVENTION

The present invention relates to a method of forming an isolation layer in a semiconductor device, and more particularly relates to a method of forming an isolation layer in a semiconductor device capable of filling a trench without generating a seam using a difference in growth rate of a O₃-TEOS layer caused by the particular kind of underlayer exposed at the bottom of the trench.

As semiconductor devices become more highly-integrated, a process for forming an isolation layer becomes more difficult. Accordingly, the isolation layer is formed through a shallow trench isolation (STI) method in which a trench is formed on a semiconductor substrate and the trench is then filled. On the other hand, the STI method is divided into various kinds of methods. One such STI method is to etch sequentially a gate insulating layer, a polysilicon layer and a hard mask formed in a layered structure on a semiconductor substrate for forming a trench, and to form an oxide layer on the entire structure for filling the trench.

However, in a highly integrated device, a depth of the trench is deep, as compared with a width of entrance of the trench, and so it is very difficult to fill the trench without generating a void. That is, when the trench is filled with an oxide layer, the deposition rate of oxide on the entrance of the trench is higher than that of oxide on the bottom surface of the trench, and so an overhang is generated while the oxide layer is formed. Due to the above-described overhang, the entrance of the trench is clogged so that a void is generated in the oxide layer with which the trench is filled.

In general, a high density plasma (HDP) oxide layer having an excellent gap-filling characteristic has been used for gap-filling the trench. As the semiconductor devices become more highly-integrated, however, the oxide layer forming method using the conventional HDP process has reached the limits of the deposition equipment so that it becomes difficult to gap-fill the trench.

Recently, instead of the oxide layer forming method using the conventional HDP process, the method in which a O₃-TEOS (tetra ethyl ortho silicate) layer is formed to gap-fill a trench has been introduced. However, while the O₃-TEOS layers are formed on opposing side walls, the formed O₃-TEOS layers come into contact with each other to form a seam, and a portion of the O₃-TEOS layer in which the seam is generated is porous. Due to the above-described porosity of the O₃-TEOS layer, once a wet etching process as the subsequent process is performed, the seam is exposed so that an abnormal etching shape is obtained.

### SUMMARY OF THE INVENTION

The present invention discloses a method of forming an isolation layer in a semiconductor device which can prevent the insulating layers formed on the opposing side walls of a trench from coming into contact with each other, to inhibit a generation of seam and to enhance filling of the trench.

A method of forming an isolation layer in a semiconductor device according to one embodiment comprises the steps of providing a semiconductor substrate on which a trench is formed; forming spacers on side walls of the trench; forming a first insulating layer to fill a portion of the trench such that a deposition rate of the first insulating layer on the semiconductor substrate which is a bottom surface of the trench and exposed between the spacers is higher than that on surfaces of the spacers; and forming a second insulating layer on the first insulating layer so as to fill the trench with the second insulating layer.

In the above method, the step of forming the spacer can include the steps of forming a liner-shaped insulating layer on the entire semiconductor substrate on which the trench is formed, and etching a portion of the insulating layer through a spacer-etching process to form the spacers on side walls of the trench and expose the semiconductor substrate as the bottom surface of the trench. In addition, the spacer can be formed of an oxide layer or a nitride layer and the spacer can be formed of any one of a plasma enhanced-tetra ethyl ortho silicate (PE-TEOS) layer, a thermal oxide layer, a plasma enhanced-SiN (PE-SiN) layer and a LP-Si₃N₄ layer.

The first insulating layer preferably is formed of a O₃-tetra ethyl ortho silicate (TEOS) layer and formed through a plasma enhanced chemical vapor deposition (PECVD) method or a low pressure chemical vapor deposition (LPCVD) method. The second insulating layer preferably is formed of a O₃-TEOS layer or a high density plasma (HDP) oxide layer. The method of the present invention can further include the steps of forming a side wall oxide layer on a side wall of the trench before forming the spacer; and forming a liner insulating layer on the side wall oxide layer.

### BRIEF DESCRIPTION OF THE DRAWINGS

The above and other features and advantages of the present invention will become readily apparent by reference to the following detailed description when considered in conjunction with the accompanying drawings wherein:

FIG. 1A to FIG. 1F are sectional views of a semiconductor device for illustrating a method of forming an isolation layer in a semiconductor device according to an embodiment of the present invention.

### DESCRIPTION OF SPECIFIC EMBODIMENTS

Hereinafter, the preferred embodiment of the present invention will be explained in more detail with reference to the accompanying drawings. However, the embodiments of the present invention may be modified variously and a scope of the present invention should not be limited to the embodiment described below. The description herein is provided for illustrating the invention more completely to those skilled in the art.

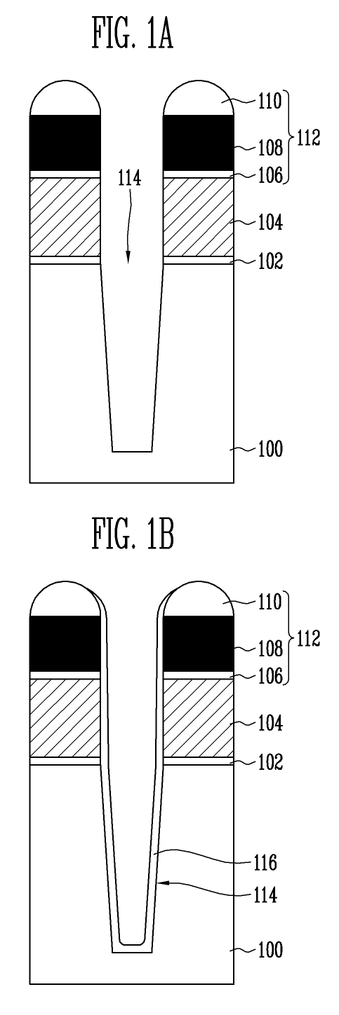

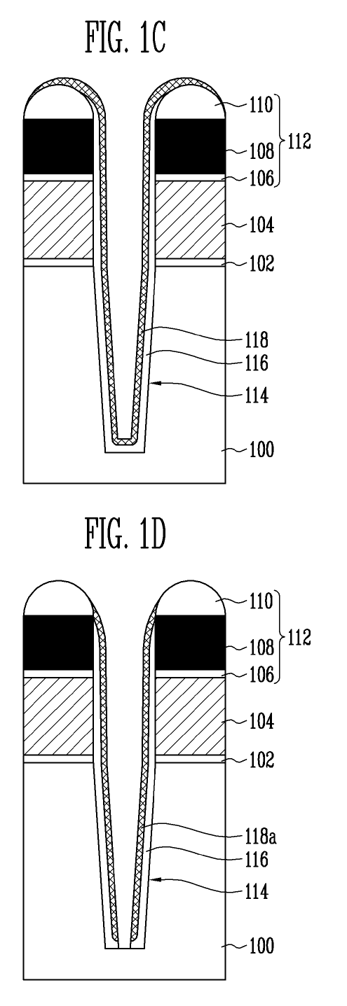

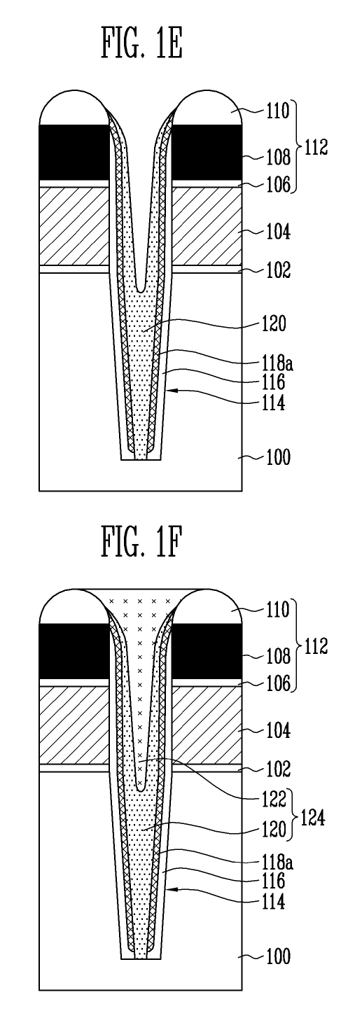

FIG. 1A to FIG. 1F are sectional views of a semiconductor device for illustrating a method of forming an isolation layer in a semiconductor device according to an embodiment of the present invention.

Referring to FIG. 1A, a gate insulating layer 102, a conductive layer 104 and an isolation mask 112 are sequentially formed on a semiconductor substrate 100. The gate insulating layer 102 can be formed of a silicon dioxide (SiO₂) layer. In a case where the gate insulating layer is formed of a silicon dioxide layer, the gate insulating layer may be formed through an oxidation process. In a flash memory device, on the other hand, the gate insulating layer 102 preferably is formed of a tunnel oxide layer. The conductive layer 104 is used as a gate electrode in a semiconductor device, and may be formed of a polysilicon layer, a metal layer, or a stacked layer of a polysilicon layer and a metal layer. If the conductive layer 104 is used as a floating gate in a semiconductor device, the conductive layer may be formed of a polysilicon layer, a metal layer, or a stacked layer of a polysilicon layer and a metal layer. In a flash memory device having a SONOS (silicon-oxide-nitride-oxide-silicon) structure, on the other hand, a nitride layer preferably is formed in place of the conductive layer 104 and is used as an electron storage layer. The isolation mask 112 can be formed of a stacked layer including or consisting of buffer oxide layer 106, a nitride layer 108 and a hard mask 110. The hard mask 110 may be formed of a nitride layer, an oxide layer or an amorphous carbon layer.

Subsequently, the isolation mask 112, the conductive layer 104 and the gate insulating layer 102 in the desired isolation area are sequentially etched by an etching process using a mask (not shown) to expose the isolation area of the semiconductor substrate 100. The above process is described in more detail as follows.

A photoresist is applied on the isolation mask 112 to form a photoresist layer (not shown), and an exposure process and developing process are carried out to form a photoresist pattern (not shown) through which the isolation mask 112 in the isolation layer area is exposed. Subsequently, the isolation area of the isolation mask 112 is etched through one or more etching processes using the photoresist pattern. The photoresist pattern is then removed. In succession, the conductive layer 104 and the gate insulating layer 102 are etched through one or more etching processes using the isolation mask 112, and so the isolation area of the semiconductor substrate 100 is exposed. In a process of etching the nitride layer 108, the buffer oxide layer 106, the conductive layer 104 and the insulating layer 102, the hard mask 110 also can be etched by a certain thickness. Subsequently, the semiconductor substrate 100 corresponding to the exposed isolation area is etched through an etching process to form a trench 114.

Referring to FIG. 1B, to recover from etching damage generated on a side wall and a bottom surface of the trench 114 during an etching process performed for forming the trench 114, an oxidation process may be further carried out. Thus, the side wall and the bottom surface of the trench 114 are oxidized through the oxidation process so that an etching-damaged layer (not shown) becomes a side wall oxide layer 116. On the other hand, the side wall and the bottom surface of the trench 114 as well as side wall of the gate insulating layer 102 the conductive layer 104 and the isolation mask 112 are oxidized by a certain thickness through the oxidation process. In this case, the side wall oxide layer 116 is formed, a relatively large quantity of silicon component is distributed on a side wall and a bottom surface of the trench 114, and so the side wall oxide layer 116 is formed more thickly on a side wall and a bottom surface of the trench 114. In addition, to improve a trench filling characteristic, a liner insulating layer (not shown) may be formed on the side wall oxide layer 116. In one embodiment, the liner insulating layer may be formed of an oxide layer or a nitride layer.

Referring to FIG. 1C, insulative material is deposited on a surface of the entire structure including the trench 114 until a portion of the trench 114 is filled with insulative material to form a liner-shaped first insulating layer 118 for a spacer. The first insulating layer 118 may be formed of an oxide layer or a nitride layer. Preferably, the first insulating layer 118 is formed of any one of a PE-TEOS (plasma enhanced-tetra ethyl ortho silicate) layer, a thermal oxide layer, a PE-SiN layer, and a LP-Si₃N₄ layer.

Referring to FIG. 1D, a spacer-etching process is performed to etch the first insulating layer 118. A dry etching process may be utilized as the spacer etching process. Preferably, an etchback process can be utilized as the space etching process. At this time, during the spacer-etching process, at least substantially all the horizontal portions of the first insulating layer 118 are removed and only a vertical portion which is thicker than the horizontal portions remains in the trench 114, and so a spacer 118a is formed over side walls of the trench 114, the gate insulating layer 102, the conductive layer 104 and the isolation mask 112.

Together with the first insulating layer, on the other hand, the side wall oxide layer 116 exposed between the spacers 118a is removed during the spacer-etching process in which the spacer 118a is used as a mask. Accordingly, the side wall oxide layer 116 between the spacers 118a and on a bottom surface of the trench 114 is removed so that a surface of the semiconductor substrate 100 between the spacers 118a is exposed.

In addition, if a liner insulating layer is formed on the side wall oxide layer 116, the liner insulating layer exposed between the spacers 118 is removed during the spacer-etching process in which the spacer 118a is utilized as a mask, and the exposed side wall oxide layer 116 is then etched together with the liner insulating layer to expose the semiconductor substrate 100 which is a bottom surface of the trench.

Referring to FIG. 1E, to fill a portion of the trench 114, insulative material is deposited to form a second insulating layer 120 in the trench 114. The second insulating layer 120 can be formed of a O₃-TEOS layer for enhancing a gap-fill capability. In one embodiment, the O₃-TEOS layer can be formed through a chemical vapor deposition (CVD) method, preferably, a plasma enhanced-chemical vapor deposition (PECVD) method or a low pressure-chemical vapor deposition (LPCVD) method. In particular, the deposition rate of the O₃-TEOS layer is varied according to the kind of the under layer. Various deposition rates of the O₃-TEOS layer are shown in Table 1.

TABLE 1

| | | Deposition rate | |
|---|---|---|---|
| Kind of under layer | Usage of O₃ | (Å/min.) | Ratio |
| Bare Silicon Wafer | 10 g/Nm³ | 680 | 1 |
| Bare Silicon Wafer | 110 g/Nm³ | 634 | 0.93 |
| Thermal oxide layer | 10 g/Nm³ | 462 | 0.63 |
| Thermal oxide layer | 110 g/Nm³ | 536 | 0.79 |
| PE-SiN layer | 110 g/Nm³ | 401 | 0.59 |
| PE-TEOS layer | 110 g/Nm³ | 423 | 0.62 |
| LP-Si₃N₄ | 110 g/Nm³ | 399 | 0.59 |
| Poly silicon layer | 110 g/Nm³ | 564 | 0.83 |

Referring to the above Table 1, a deposition rate of the O₃-TEOS layer having a bare silicon wafer as the under layer is highest, followed by the O₃-TEOS layer having a poly silicon layer as the under layer, the O₃-TEOS layer having a thermal oxide layer as the under layer, the O₃-TEOS layer having a PE-TEOS layer as the under layer and the O₃-TEOS layer having a LP-Si₃N₄ layer as the under layer. As compared with an oxide layer and a nitride layer, accordingly, a growth rate of the O₃-TEOS layer having a bare silicon wafer as the under layer is high.

In the present invention, the side wall oxide layer 116 between the spacers 118 is etched to expose the semiconductor substrate 100 which is a bottom surface of the trench 114. In one embodiment, the semiconductor substrate 100 is substantially the bare silicon wafer. Accordingly, if the second insulating layer 120 is formed of a O₃-TEOS layer formed through a PECVD method or a LPCVD method, a deposition rate of the O₃-TEOS layer on the semiconductor substrate 100 which is a bottom surface of the trench 114 and is the bare silicon wafer is higher than that of the O₃-TEOS layer on the spacer 118a formed of the oxide layer or the nitride layer, and so a growth rate of the O₃-TEOS layer on a bottom surface of the trench 114 is higher than that of the O₃-TEOS layer on the opposing spacers 118a of the trench 114. Due to the above phenomenon, during a process for forming the second insulating layer 120 formed of the O₃-TEOS layer in the trench 114, it is possible to prevent the seam caused by a contacting between the second insulating layers 120 formed on side walls of the opposing spacers 118a of the trench 114 from being generated by the O₃-TEOS layer which is rapidly grown on a bottom surface of the trench 114.

As described above, in the present invention, the semiconductor substrate 100 which is a bottom surface of the trench 114 is exposed to maximize a difference of deposition rate between the O₃-TEOS layer on a bottom surface and the O₃-TEOS layer on side walls of the trench 114. The difference of growth rate between the O₃-TEOS layer on a bottom surface of the trench 114 and the O₃-TEOS layer on side walls of the trench 114 is maximized by the above maximized difference of deposition rates, and so it is possible to inhibit a generation of the seam at the time of forming the second insulating layer 120 in the trench 140 to enhance a gap filling characteristic for the trench 114.

Referring to FIG. 1F, insulative material is deposited on the second insulating layer 120 to fill completely the trench 114 and form a third insulating layer 122. All kinds of oxide layers are applicable to the third insulating layer 122. Preferably, the third insulating layer is formed of an O₃-TEOS layer or a high density plasma (HDP) oxide layer. In one embodiment, the third insulating layer 122 is formed of the O₃-TEOS layer, and the third insulating layer 122 and the second insulating layer 120 may be simultaneously performed during a process for forming the second insulating layer 120 by extending the deposition time. With this method, an isolation layer 124 including the second insulating layer 120 and the third insulating layer 122 is formed.

In the present invention, the semiconductor substrate which is a bottom surface of the trench is exposed while the spacer is formed when the insulating layer formed of a O₃-TEOS layer is formed in the trench, and so a deposition rate of the O₃-TEOS layer on the semiconductor substrate is higher that that of the O₃-TEOS layer on the spacer formed of an oxide layer or a nitride layer. Accordingly, the method of the present invention can prevent the insulating layers formed on the opposing side walls of a trench from coming into contact with each other to inhibit a generation of seam and to enhance of the filling characteristic for the trench.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming an isolation layer in a semiconductor device, comprising the steps of;
providing a semiconductor substrate on which a trench is formed;
forming spacers on side walls of the trench;
forming a first insulating layer to fill a portion of the trench such that a deposition rate on the semiconductor substrate which is a bottom surface of the trench is higher than that on the surfaces of the spacers; and
forming a second insulating layer on the first insulating layer so as to fill the trench with the second insulating layer.

2. The method of forming an isolation layer in a semiconductor device of claim 1, wherein the step of forming the spacer comprises the steps of;
forming a liner-shaped insulating layer on the entire semiconductor substrate on which the trench is formed; and
etching a portion of the insulating layer through a spacer-etching process to form the spacers on side walls of the trench and expose the semiconductor substrate as the bottom surface of the trench.

3. The method of forming an isolation layer in a semiconductor device of claim 1, further comprising forming the spacers of an oxide layer or a nitride layer.

4. The method of forming an isolation layer in a semiconductor device of claim 1, further comprising forming the spacers of any one of a plasma enhanced-tetra ethyl ortho silicate (PE-TEOS) layer, a thermal oxide layer, a plasma enhanced-SiN (PE-SiN) layer and a LP-Si₃N₄ layer.

5. The method of forming an isolation layer in a semiconductor device of claim 1, further comprising forming the first insulating layer of a O₃-tetra ethyl ortho silicate (TEOS) layer.

6. The method of forming an isolation layer in a semiconductor device of claim 1, further comprising forming the first insulating layer through a plasma enhanced chemical vapor deposition (PECVD) method or a low pressure chemical vapor deposition (LPCVD) method.

7. The method of forming an isolation layer in a semiconductor device of claim 1, further comprising forming the second insulating layer of a O₃-Tetra Ethyl Ortho Silicate (TEOS) layer or a high density plasma (HDP) oxide layer.

8. The method of forming an isolation layer in a semiconductor device of claim 1, further comprising the steps of;
forming a side wall oxide layer on at least a side wall of the trench before forming the spacers; and
forming a liner insulating layer on at least the side wall oxide layer.

9. The method of forming an isolation layer in a semiconductor device of claim 8, wherein any side wall oxide layer and any liner insulating layer formed on a bottom surface of the trench are removed through the spacer-etching process at the time of forming the spacer.
